(19) United States
(12) Patent Application Publication
(10) Pub. No.: US 2015/0179270 A1
(43) Pub. Date: Jun. 25, 2015

(54) Method and System for Reducing the Size of Nonvolatile Memories

(71) Applicant: Infineon Technologies AG, Neubiberg (DE)

(72) Inventors: Thomas Kern, Muenchen (DE); Jens Rosenbusch, Muenchen (DE); Ulrich Backhausen, Taufkirchen (DE); Thomas Nirschl, Putzbrunn (DE)

(21) Appl. No.: 14/641,496

(22) Filed: Mar. 9, 2015

Related U.S. Application Data
(63) Continuation of application No. 13/743,409, filed on Jan. 17, 2013, now abandoned.

(51) Int. Cl. G11C 16/14; G11C 16/26

(52) U.S. Cl. CPC G11C 16/14; G11C 16/26

(57) ABSTRACT

Embodiments relate to system and methods including a plurality of nonvolatile memory elements wherein sets of least two nonvolatile memory elements each share one select element for selecting one of the nonvolatile memory elements of a particular one of the sets of nonvolatile memory elements for a read operation or a program operation.

### CROSS REFERENCE TO RELATED APPLICATIONS

This application is a Continuation Patent Application claiming priority to U.S. patent application Ser. No. 13/743,409 filed with the U.S. Patent and Trademark Office on Jan. 17, 2013 in the name of Thomas Kern, et al. entitled “Method and System for Reducing the Size of Nonvolatile Memories” which is hereby incorporated in its entirety.

### FIELD

The present disclosure relates generally to methods and systems for reducing the size of electronically programmable nonvolatile memory, and—in particular—the physical size of embedded flash memory such as hot source triple poly (HS3P) flash memory in an integrated circuit.

### BACKGROUND

Currently, shrinking eNVM modules becomes more and more difficult when using manufacturing technologies for integrated circuits with gate lengths below 40 nm. On the one hand, the voltages to operate the embedded nonvolatile memories typically may not be reduced to a substantial extent even if the minimum feature size in the embedded nonvolatile memories is reduced below 40 nm. This results in that the main peripheral part of the eNVM modules may not be shrunk either. Consequently, the main potential to reduce the size and with it the complexity of the embedded nonvolatile memories currently moves towards several fundamental limits.

One of the limits results from the fact that also the CMOS manufacturing technologies used to produce the embedded nonvolatile memories may eventually reach their integration density limit. A further limit may be set by physical limits within a memory cell—i.e. memory cell limits—due to a coupling ratio limit and the punch trough robustness of active devices in a memory cell.

Hence, the limits may lead to a total storage capacity of embedded non-volatile memories that might be too low or too costly in terms of required chip area. However, the ever increasing demand of storage capacity within an embedded memory of an automotive electronic control unit (ECU) in conjunction with the highly competitive market structure of the automotive industry require that the above limits may be overcome.

### SUMMARY

A method and system for reducing the size of nonvolatile memory is provided, substantially as shown in and/or described in connection with at least one of the figures, as set forth more completely in the claims.

Further features and advantages of embodiments will become apparent from the following detailed description made with reference to the accompanying drawings.

### BRIEF DESCRIPTION OF THE DRAWINGS

The accompanying drawings are included to provide a further understanding and are incorporated in and constitute a part of this specification. The drawings relate to examples and embodiments and together with the description serve to explain the principles of the disclosure. Other embodiments and many of the intended advantages of embodiments will be readily appreciated as they become better understood by reference to the following detailed description.

FIG. 1a shows a schematic of two conventional neighboring nonvolatile memory cells based on floating gate transistors as nonvolatile memory elements, wherein each memory cell comprises its own selection transistor for selecting the memory cell's floating gate transistor for a read or a program operation.

FIG. 1b shows a schematic of a single two-bit nonvolatile memory cell according to an embodiment based on floating gate transistors as nonvolatile memory elements, wherein the memory cell comprises a single select transistor for selecting one of the memory cell's floating gate transistors for a read or a program operation. Since the embodiment of the memory cell in FIG. 1b comprises two control gates (2CG) of the two floating gate transistors and a single select gate (1SG) of the single select transistor, the memory cell may also be referred to as 2CG1SG memory cell.

FIG. 2a shows a schematic of a 2CG1SG memory cell according to an embodiment, wherein voltages for two example biasing cases are shown next to the respective terminals of the 2CG1SG memory cell, the biasing cases for both: reading the nonvolatile memory content of the left floating gate transistor via the left control gate (CGL) in the first or left alternative, and reading the nonvolatile memory content of the right floating gate transistor via the right control gate (CGR) in the second or right alternative.

FIG. 2b shows a schematic of a 2CG1SG memory cell according to an embodiment, wherein voltages for two example biasing cases are shown next to the respective terminals of the 2CG1SG memory cell, the biasing cases for both: programming the nonvolatile memory content of the left floating gate transistor via the left control gate (CGL) in the first or left alternative, and programming the nonvolatile memory content of the right floating gate transistor via the right control gate (CGR) in the second or right alternative.

FIG. 2c shows a schematic of a 2CG1SG memory cell according to an embodiment, wherein voltages for one example biasing case are shown next to the respective terminals of the 2CG1SG memory cell, the biasing case for erasing the nonvolatile memory content of the left floating gate transistor via the left control gate (CGL) and erasing the nonvolatile memory content of the right floating gate transistor via the right control gate (CGR) at the same time.

FIG. 3a shows a schematic of an array of 2CG1SG memory cells, wherein each 2CG1SG memory cell may be placed in a virtual ground organization and every contact to a shared bit-or-source line may be shared among four 2CG1SG memory cells.

FIG. 3b shows a possible layout of an array of 2CG1SG memory cells, wherein each 2CG1SG memory cell may be placed in a virtual ground organization and every contact to a shared bit-or-source line may be shared among four 2CG1SG memory cells.

FIG. 4 shows a schematic of a 2CG1SG memory cell according to an embodiment for complement sensing of nonvolatile memory content. In the shown embodiment, only the right floating gate transistor of the 2CG1SG memory cell may be used to store actual data while the left floating gate transistor of the 2CG1SG memory cell may be used to store the respective inverted data serving as a local reference. I.e. the left floating gate transistor may remain erased or may be programmed depending on the value of the data to store in the right floating gate transistor.

FIG. 5a shows a schematic of a 2CG1SG memory cell according to an embodiment, wherein a copy function may be initiated to copy a nonvolatile memory content with inversion from the right floating gate transistor to the left floating gate transistor.

FIG. 5b shows a schematic of a 2CG1SG memory cell according to an embodiment, wherein a suitable bias voltage to the control gate of the right floating gate transistor may cause a programming current for the left floating gate transistor in case the right floating gate transistor is in an erased state.

FIG. 5c shows a schematic of a 2CG1SG memory cell according to an embodiment, wherein a programmed state of the right floating gate transistor may suppress a programming current for the left floating gate transistor such that the left floating gate transistor may remain in an erased state.

FIG. 6 shows a flow diagram of an embodiment for a method for managing two bits of information in each of a plurality of nonvolatile memory cells, wherein each nonvolatile memory cell comprises a first floating gate transistor, a second floating gate transistor, and a select transistor.

### DETAILED DESCRIPTION

In the following, for illustration purposes, the invention will be described with reference to flash memory as embedded nonvolatile memory (eNVM) for automotive applications. However, the invention is not so limited and may find its application in conjunction with reducing the size of any other kind of nonvolatile memory.

In the following detailed description, reference is made to the accompanying drawings, which form a part hereof, and in which are shown by way of illustration specific embodiments. It is to be understood that other embodiments may be utilized and structural or other changes may be made without departing from the scope of the present disclosure. The following detailed description, therefore, is not to be taken in a limiting sense, and the scope of the present disclosure is defined by the appended claims.

Embodiments of the disclosure may comprise two memory stacks or memory elements—e.g. floating gate transistors—sharing one select element—e.g. a select transistor—to select one of the two memory stacks for reading or programming. In embodiments, the biasing for the memory elements may be provided by only two multifunctional lines per memory cell—e.g. shared bitlines or source lines (in the following shared bit-or-source lines). This may lead to an equivalent shrink of a memory cell of approximately 80% for the memory cell at a feature size of 40 nm.

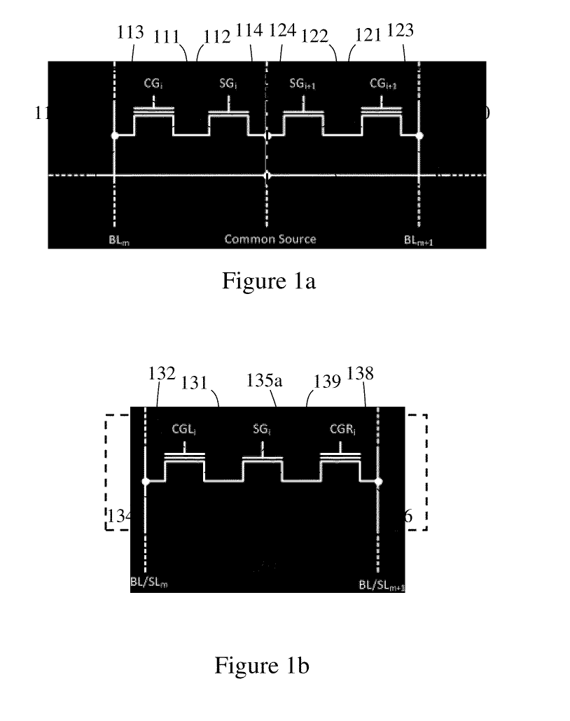

An example for this reduction in size for storing two bits in a single memory cell may been seen by comparing two memory cells of a conventional HS3P memory cell array in FIG. 1a with a 2CG1SG memory cell according to an embodiment in an HS3P memory cell array in a virtual ground configuration. Therein, FIG. 1a shows a first conventional HS3P flash memory cell 110 with a first floating gate transistor 111 connected with its drain to a first bitline 115 of the first memory cell 110. The gate of the first floating gate transistor 111 may be connected to a first control gate line 113. The source of the first floating gate transistor 111 is connected to the drain of a first select transistor 112 of the first memory cell 110. The gate of the first select transistor 112 is connected to a first select gate line 114. The source of the first select transistor 112 in turn is connected to a common source line 120a of the first memory cell 110 and a neighboring second memory cell 120. The second memory cell 120 comprises its own second select transistor 122 which is also connected to the common source line 120a. The gate of the second select transistor 122 is connected to a second select gate line 124. The drain of the second select transistor 124 is connected to the source of a second floating gate transistor 121 of the second memory cell 120. Moreover, the gate of the second floating gate transistor 121 is connected to a second control gate line 123. Finally, the second floating gate transistor 121 is connected with its drain to a second bitline 125 of the second memory cell 120.

In contrast to the above, FIG. 1b shows a schematic of a single two-bit nonvolatile memory cell according to an embodiment based on floating gate transistors as nonvolatile memory elements in the previously mentioned 2CG1SG configuration. Unlike the two conventional HS3P flash memory cells 110 and 120 in FIG. 1a, the 2CG1SG memory cell 130 as shown in FIG. 1b may comprise a single select transistor 135b to select one of a first floating gate transistor 131 or a second floating gate transistor 139 for a read operation or a program operation. For that purpose, the select transistor 135b of the 2CG1SG memory cell 130 may be connected with its drain to the source of the first floating gate transistor 131 and with its source to the drain of the second floating gate transistor 139. The drain of the first floating gate transistor 131 in turn may be connected to a first shared bit-or-source line 134 of the 2CG1SG memory cell 130 while the source of the second floating gate transistor 139 may be connected to a second shared bit-or-source line 136. The gate of the first floating gate transistor 131 may be connected to a first control gate line 132, the gate of the second floating gate transistor 139 may be connected to a second control gate line 138, and the gate of the select transistor 135b may be connected to a common select gate line 135a. In this way, the single select transistor 135b may be shared for managing, e.g. accessing or manipulating nonvolatile memory content stored in the first floating gate transistor 131 and in second floating gate transistor 139.

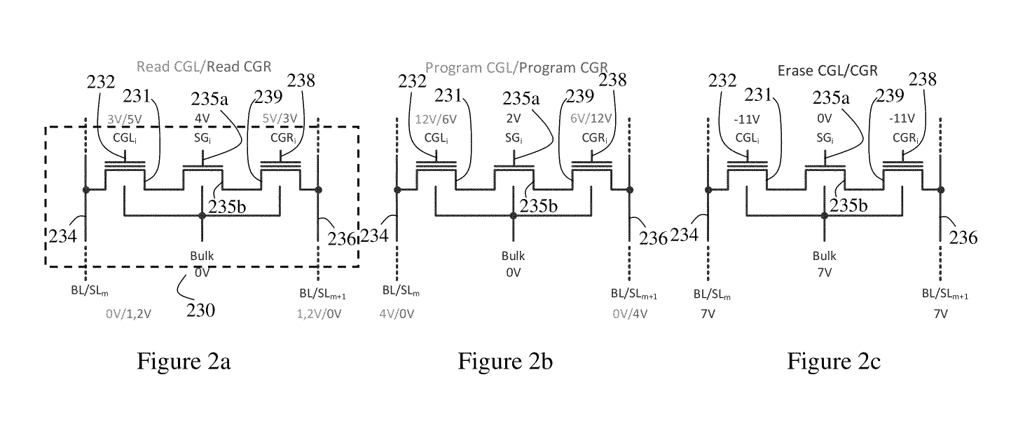

In the following, the series of FIGS. 2a to 2c will be described. These figures show example biasing cases for reading, programming or erasing a first floating gate transistor 231 and a second floating gate transistor 239 of a two-bit 2CG1SG memory cell 230. In this regard, FIG. 2a shows a schematic of the 2CG1SG memory cell 230. As shown, the structure of this memory cell may correspond to the structure of the 2CG1SG memory cell 130 in FIG. 1b, wherein corresponding items have been designated with reference numbers that exhibit the same two rightmost digits.

In the embodiment of FIG. 2a, voltages for two example biasing cases for reading the 2CG1SG memory cell 230 are shown next to the respective terminals of the 2CG1SG memory cell 230. In both cases, a voltage of 4 V may be supplied to the select gate line 235a to select one of the first floating gate transistor 231 or the second floating gate transistor 239 for reading. Moreover, the bulk terminals of the first floating gate transistor 231, the select transistor 235b and second floating gate transistor 239 may be biased at 0 V. Then, firstly, in the first or left alternative, an example biasing case for reading the nonvolatile memory content of the left floating gate transistor 231 via the left control gate (CGL) is shown. In this first biasing case, a first read voltage of 3 V may be supplied at the left control gate line 232, while a second read voltage of 5 V may be supplied at the right control gate line 238. In this case, the left shared bit-or-source line 234 in FIG. 2a may act as a source line to which a first source voltage of 0 V may be supplied, while the right shared bit-or-source line 236, as shown in FIG. 2a, may act as a bitline to which a first bitline voltage of 1.2 V may be supplied. Biased as described above, depending on a first bit of the nonvolatile memory content of the nonvolatile memory content of 2CG1SG memory cell 230 stored in the left or first floating gate transistor 231 and as represented by the presence of a charge of the floating gate of the left floating gate transistor 231, the first bit of the nonvolatile memory content of 2CG1SG memory cell 230 may be read and signaled to the exterior of the 2CG1SG memory cell 230 by either drawing a current from the bitline 236 or not.

In this embodiment, an increased second read voltage of 5 V may be supplied at the right control gate line 238 to suppress parasitic impacts of the right or second floating gate transistor 239 on the reading current and, hence, a narrowing of the reading current window. As it is clear to the skilled person, the voltage bias conditions as shown in FIG. 2a as well as the following FIGS. 2b and 2c only reveal examples for possible biasing conditions to read, program or erase the 2CG1SG memory cell 230.

Secondly, in the second or right alternative, FIG. 2a shows an example biasing case for reading the nonvolatile memory content of the right floating gate transistor 239 via the right control gate (CGR). In this second biasing case, a third read voltage of 5 V may be supplied at the left control gate line 232, while a fourth read voltage of 3 V may be supplied at the right control gate line 238. In this case, the left shared bit-or-source line 234 in FIG. 2a may act as a bitline to which a second bitline voltage of 1.2 V may be supplied, while the right shared bit-or-source line 236, as shown in FIG. 2a, may act as a source line to which a second source line voltage of 0 V may be supplied. Biased as described above, depending on a second bit of the nonvolatile memory content of 2CG1SG memory cell 230 stored in the right or second floating gate transistor 239 and as represented by the presence of a charge of the floating gate of the right floating gate transistor 239, the second bit of the nonvolatile memory content of 2CG1SG memory cell 230 may be read and signaled to the exterior of the 2CG1SG memory cell 230 by either drawing a current from the bitline 234 or not.

In the embodiment of FIG. 2b, voltages for two example biasing cases for programming the 2CG1SG memory cell 230 are shown next to the respective terminals of the 2CG1SG memory cell 230. In both cases, a voltage of 2 V may be supplied to the select gate line 235a to select one of the first floating gate transistor 231 or the second floating gate transistor 239 for programming. Moreover, the bulk terminals of the first floating gate transistor 231, the select transistor 235b and second floating gate transistor 239 may be biased at 0 V. Then, firstly, in the first or left alternative, an example biasing case for programming the nonvolatile memory content of the left floating gate transistor 231 via the left control gate (CGL) is shown. In this first biasing case, a first program voltage of 12 V may be supplied at the left control gate line 232, while a second program voltage of 6 V may be supplied at the right control gate line 238. In this case, the left shared bit-or-source line 234 in FIG. 2b may act as a bitline to which a third bitline voltage of 4 V may be supplied, while the right shared bit-or-source line 236, as shown in FIG. 2b, may act as a source line to which a third source line voltage of 0 V may be supplied. Biased as described above, a first bit of the nonvolatile memory content of the 2CG1SG memory cell 230 stored in the left or first floating gate transistor 231 may be programmed by transferring a charge onto the floating gate of the left floating gate transistor 231 by a programming current induced between the bitline 234 and the source line 236 by the increased third bitline voltage of 4 V and the increased first program voltage of 12 V at the control gate of the first floating gate transistor 231.

In this embodiment, an increased second program voltage of 6 V may be supplied at the right control gate line 238 to suppress parasitic impacts of the right or second floating gate transistor 239 on the programming current and, hence, a narrowing of the programming current window.

Secondly, in the second or right alternative, FIG. 2b shows an example biasing case for programming the nonvolatile memory content of the right floating gate transistor 239 via the right control gate (CGR). In this second biasing case, a third program voltage of 6 V may be supplied at the left control gate line 232, while a fourth program voltage of 12 V may be supplied at the right control gate line 238. In this case, the left shared bit-or-source line 234 in FIG. 2b may act as a source line to which a fourth source line voltage of 0 V may be supplied, while the right shared bit-or-source line 236, as shown in FIG. 2b, may act as a bitline to which a fourth bitline voltage of 4 V may be supplied. Biased as described above, a second bit of the nonvolatile memory content of the 2CG1SG memory cell 230 stored in the right or second floating gate transistor 239 may be programmed by transferring a charge onto the floating gate of the right floating gate transistor 239 by a programming current induced between the bitline 236 and the source line 234 by the increased fourth bitline voltage of 4 V and the increased fourth program voltage of 12 V at the control gate of the second floating gate transistor 239.

In the embodiment of FIG. 2c, voltages for one example biasing case for erasing the 2CG1SG memory cell 230 are shown next to the respective terminals of the 2CG1SG memory cell 230. In this case, a voltage of 0 V may be supplied to the select gate line 235a to select both the first floating gate transistor 231 and the second floating gate transistor 239 for erasing. Moreover, the bulk terminals of the first floating gate transistor 231, the select transistor 235b and second floating gate transistor 239 may be biased at 7 V. In this erasing biasing case, a first erasing voltage of −11 V may be supplied to the left control gate line 232 as well as to the right control gate line 238. In this case, the left shared bit-or-source line 234 in FIG. 2c may act as a bitline to which a fifth bitline voltage of 7 V may be supplied, while the right shared bit-or-source line 236, as shown in FIG. 2c, may also act as a bitline to which the fifth bitline voltage of 7 V may be supplied. Biased as described above, the two bits of the nonvolatile memory content of the 2CG1SG memory cell 230 stored in the left and first floating gate transistor 231 and the right or second floating gate transistor 239 may be erased by removing a charge from the floating gate of the left floating gate transistor 231 and from the floating gate of the right floating gate transistor 239 by the increased fifth bitline voltage of 7 V and the increased negative voltage of −11 V at the control gate of the first floating gate transistor 231 and at the control gate of the second floating gate transistor 239.

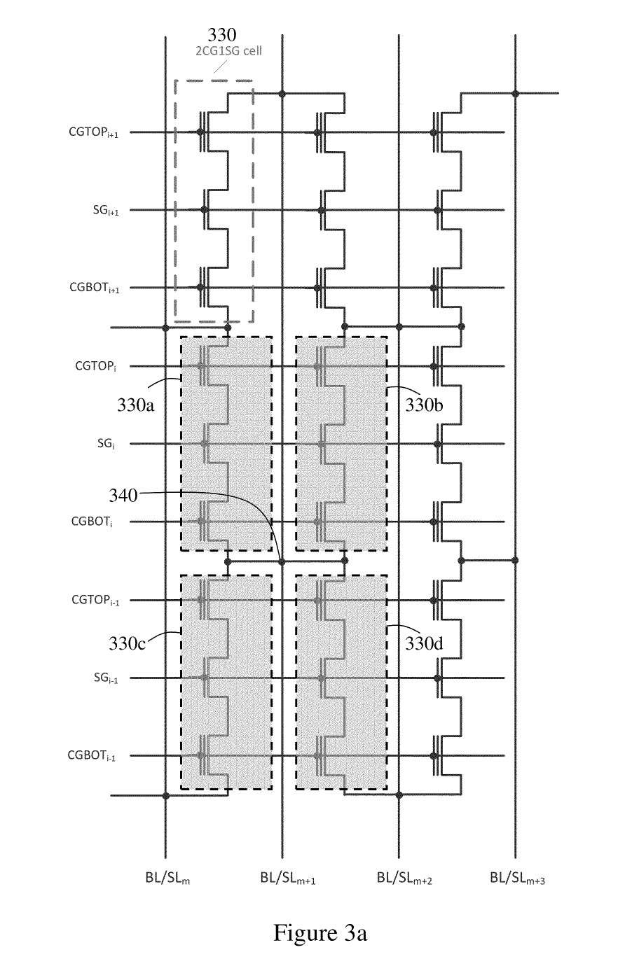

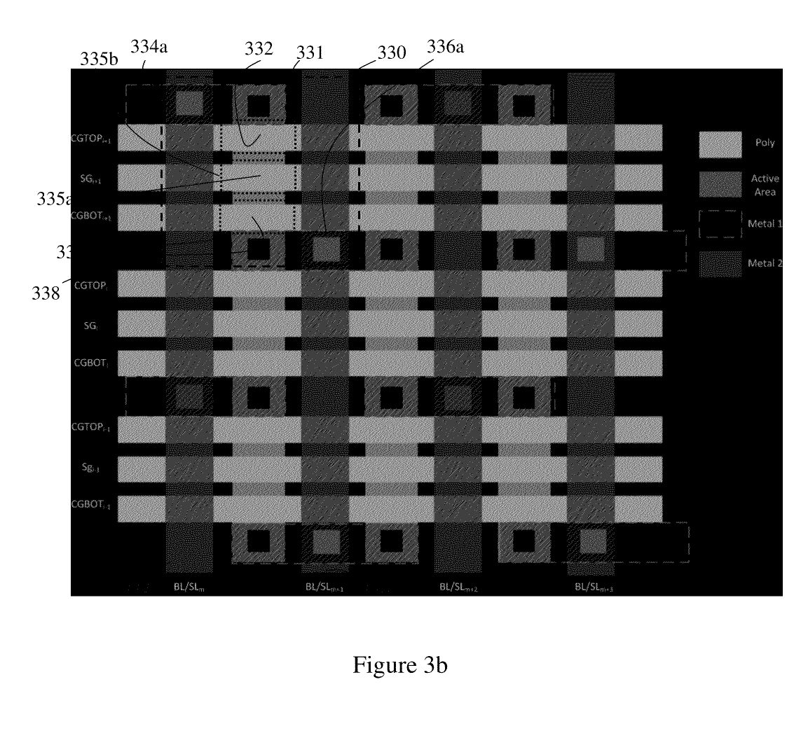

Turning to the next figure, FIG. 3a shows a schematic of an array of 2CG1SG memory cells. In this array, each 2CG1SG memory cell 330 may be placed in a virtual ground organization. I.e. the middle of the single select transistor of each 2CG1SG memory cell 330 that corresponds to the common source or ground line of a conventional array of HS3P memory cells (cf. FIG. 1a) appears to provide a virtual ground for the first and second floating gate transistors of the 2CG1SG memory cell 330. As can been seen from the four 2CG1SG memory cells 330a, 330b, 330c and 330d every contact to a shared bit-or-source line such as the contact 340 may be shared among four 2CG1SG memory cells.

The next figure, namely FIG. 3b, shows a possible layout of an array of 2CG1SG memory cells, wherein each 2CG1SG memory cell may be placed in a virtual ground organization and every contact to a shared bit-or-source line may be shared among four 2CG1SG memory cells. In the 2CG1SG memory cell 330 as surrounded by the dotted line, some layout elements have been designated with reference numbers. As in the embodiment in FIG. 3b, the structure of the 2CG1SG memory cell 330 may correspond to the structure of the 2CG1SG memory cell 130 in FIG. 1b and, hence, corresponding items have been designated with reference numbers that exhibit the same two rightmost digits.

As shown in FIG. 3b, the crossing of the uppermost horizontal poly layer strip with the leftmost vertical active area strip may define the first floating gate transistor 331, the crossing of the second horizontal poly layer strip with the leftmost vertical active area strip may define the select transistor 335b, and the crossing of the third horizontal poly layer strip with the leftmost vertical active area strip may define the second floating gate transistor 339. In the embodiment, the uppermost poly layer strip defines a first control gate line 332, the second poly layer strip may define a select gate line 335a, and the third poly layer strip may define a second control gate line 338. Moreover, the leftmost vertical metal 2 layer strip may define a first shared bit-or-source line 334, while the second vertical metal 2 layer strip may define a second shared bit-or-source line 336 of the 2CG1SG memory cell 330. As in the embodiment in FIG. 3b, the reference numbers 334a and 336a may define contacts of the first shared bit-or-source line 334 to the first floating gate transistor 331 and of the second shared bit-or-source line 336 to the second floating gate transistor 339 via horizontal metal 1 strips and further contacts respectively.

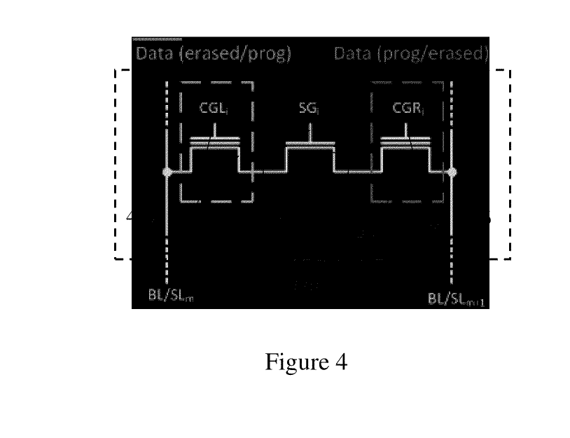

FIG. 4 shows a schematic of a 2CG1SG memory cell 430 according to a further embodiment. As in the embodiment of FIG. 4, the structure of the 2CG1SG memory cell 430 may correspond to the structure of the 2CG1SG memory cell 130 in FIG. 1b and, hence, corresponding items have been designated with reference numbers that exhibit the same two rightmost digits. The 2CG1SG memory cell 430 in FIG. 4 may be used for complement sensing of nonvolatile memory content. That means that, for instance—as in this embodiment—only the right floating gate transistor 439 of the 2CG1SG memory cell 430 may be used to store actual data while the left floating gate transistor 431 of the 2CG1SG memory cell 430 may be used to store the respective inverted data serving as a local reference. I.e. the left floating gate transistor 431 may remain erased or may be programmed depending on the value of the data to store in the right floating gate transistor 439. For this complement sensing, a serial read operation may be applied. Moreover, the inverted data serving as a local reference may also be stored in another 2CG1SG memory cell, e.g. a neighboring 2CG1SG memory cell.

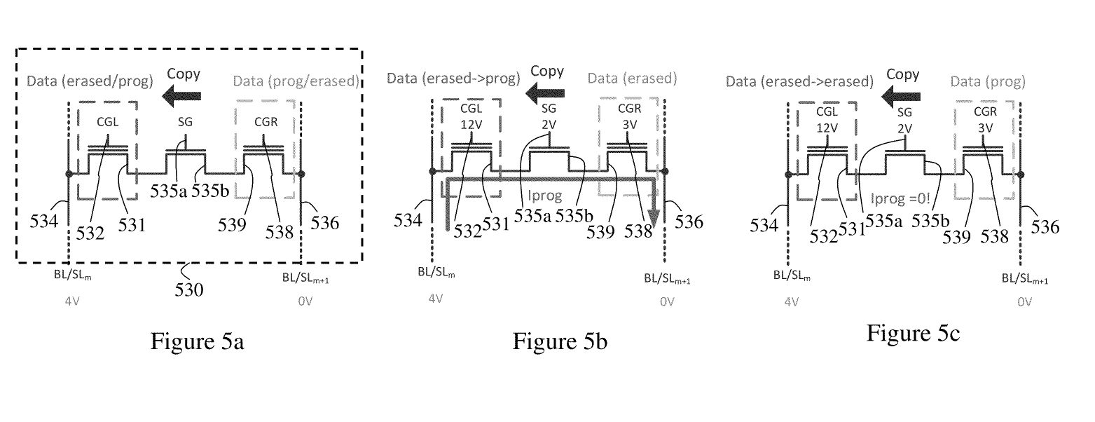

FIG. 5a shows a schematic of a 2CG1SG memory cell 530 according to an embodiment wherein a copy function may be implemented easily to copy a non-volatile memory content with inversion of the value of the memory content from the right floating gate transistor 539 to the left floating gate transistor 531. As in the embodiment in FIG. 5a, the structure of the 2CG1SG memory cell 530 may correspond to the structure of the 2CG1SG memory cell 130 in FIG. 1b and, hence, corresponding items have been designated with reference numbers that exhibit the same two rightmost digits. To prepare the copy function in the example shown in FIGS. 5a to 5c, a bitline voltage of 4 V may be provided to the first shared bit-or-source line 534 while a source voltage of 0 V may be provided to the second shared bit-or-source line 536 of the 2CG1SG memory cell 530 to eventually induce a programming current between the first shared bit-or-source line 534 and the second shared bit-or-source line 536. As described further below, this programming current will depend on a proper selection of a bias voltage provided to the right control gate line 538 and the programmed or erased state of the right floating gate transistor 539.

FIG. 5b shows a schematic of the 2CG1SG memory cell 530 according to FIG. 5a, wherein a suitable bias voltage to the control gate of the right floating gate transistor 539 may cause a programming current for the left floating gate transistor 531 in case the right floating gate transistor 539 is in erased state. For that purpose, as shown in FIG. 5b, a first copy voltage of 12 V may be provided via the first control gate line 532 to the control gate of the left or first floating gate transistor 531 and a second copy voltage of 3 V may be provided via the second control gate line 538 to the control gate of the right or second floating gate transistor 539. This biasing may lead to a programming current I_{prog} for the left floating gate transistor 531 from the first shared bit-or-source line 534 to the second shared bit-or-source line 536 in case a select voltage of 2 V is provided via the select gate line 535a to the control gate of the select gate transistor 535b and the right floating gate transistor 539 is in an erased state. As a result, the nonvolatile memory content of the erased right floating gate transistor 539 may be regarded as copied with inversion of the value of the memory content to the left floating gate transistor 531.

FIG. 5c shows a schematic of the 2CG1SG memory cell 530 according to FIG. 5a, wherein a programmed state of the right floating gate transistor 539 may suppress a programming current for the left floating gate transistor 531 such that the left floating gate transistor 531 may remain in erased state. As shown in FIG. 5c, a first copy voltage of 12 V may be provided via the first control gate line 532 to the control gate of the left or first floating gate transistor 531 and a second copy voltage of 3 V may be provided via the second control gate line 538 to the control gate of the right or second floating gate transistor 539. In this case, a programming current for the left floating gate transistor 531 may be suppressed and the left floating gate transistor 531 may remain in erased state if the right floating gate transistor 539 is in programmed state even if a select voltage of 2 V is provided via the select gate line 535a to the control gate of the select gate transistor 535b. As a result, the nonvolatile memory content of the programmed right floating gate transistor 539 may also be regarded as “copied” with inversion of the value of the memory content to the left floating gate transistor 531.

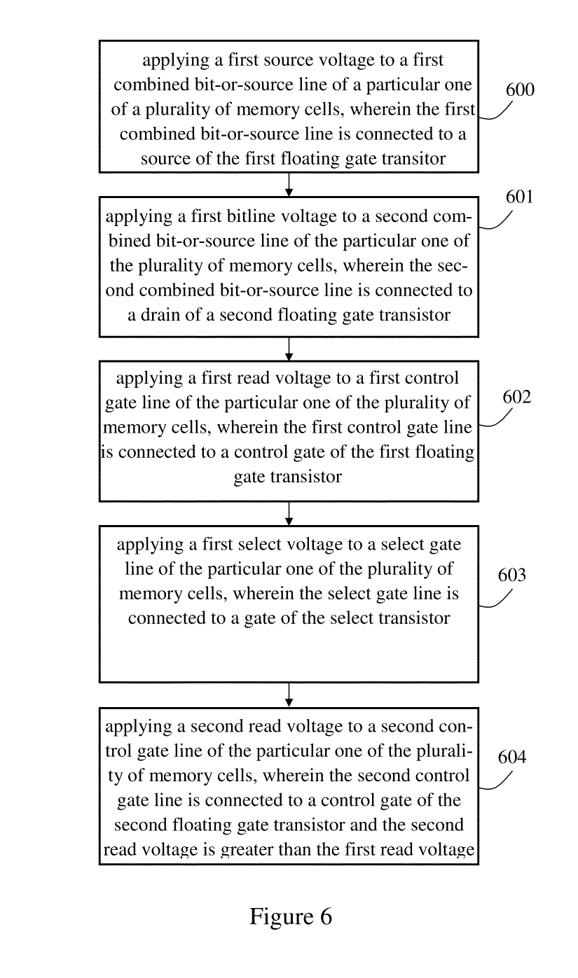

FIG. 6 shows a flow diagram of an embodiment for a method for managing two bits of information in each of a plurality of nonvolatile memory cells, wherein each nonvolatile memory cell comprises a first floating gate transistor, a second floating gate transistor, and a select transistor.

As shown in the embodiment of FIG. 6, a method for reading a nonvolatile memory content of the first floating gate transistor may comprise applying a first source voltage to a first shared bit-or-source line of a particular one of the plurality of memory cells at 600, wherein the first shared bit-or-source line is connected to a source of the first floating gate transistor.

In a further act of the method, a first bitline voltage may be applied to a second shared bit-or-source line of the particular one of the plurality of memory cells at 601, wherein the second shared bit-or-source line may be connected to a drain of a second floating gate transistor.

In another act of the method, a first read voltage may be applied to a first control gate line of the particular one of the plurality of memory cells at 602, wherein the first control gate line may be connected to a control gate of the first floating gate transistor.

According to a further act of the method, a first select voltage may be applied to a select gate line of the particular one of the plurality of memory cells at 603, wherein the select gate line may be connected to a gate of the select transistor.

Moreover, in another act of the method, a second read voltage may be applied to a second control gate line of the particular one of the plurality of memory cells at 604, wherein the second control gate line may be connected to a control gate of the second floating gate transistor, wherein the second read voltage may be greater than the first read voltage.

With respect to the above-described embodiments which relate to the Figures, it is emphasized that the embodiments basically serves to increase the comprehensibility. In addition to that, the following further embodiments try to illustrate a more general concept. However, also the following embodiments are not to be taken in a limiting sense. Rather—as expressed before—the scope of the present disclosure is defined by the appended claims.

In this regard, one embodiment relates to a nonvolatile memory device comprising a plurality of nonvolatile memory elements, wherein sets of least two nonvolatile memory elements each share one select element for selecting one of the nonvolatile memory elements of a particular one of the sets of nonvolatile memory elements for a read operation or a program operation.

In one embodiment, the sets of nonvolatile memory elements each comprise at least a first memory transistor and a second memory transistor. In this embodiment, the select element in each of the sets of nonvolatile memory elements comprises a select transistor. In embodiments, a memory functionality of the first and the second memory transistor is based on a floating gate, a nitride layer or a nano-crystal layer.

A further embodiment is adapted to apply a higher voltage to a control gate of the first memory transistor of a particular one of the sets of nonvolatile memory elements forming a combined memory cell than to a control gate of the second memory transistor of the combined memory cell to read a nonvolatile memory content of the second memory transistor.

Another embodiment of the nonvolatile memory device, for complement sensing of nonvolatile memory contents, is adapted to program data to one of a set of two nonvolatile memory elements in case the other of the set of two nonvolatile memory elements is in an erased state. Moreover, this embodiment is adapted to leave the one of the set of two nonvolatile memory elements in an erased state in case the other of the set of two nonvolatile memory elements is in programmed state.

A still further embodiment of the nonvolatile memory device is adapted to copy data to one of a set of two nonvolatile memory elements from the other of the set of two nonvolatile memory elements.

A further embodiment relates to a nonvolatile memory device comprising a plurality of combined memory cells wherein each combined memory cell comprises two memory transistors and one select transistor.

In an embodiment, a source to drain biasing for each combined memory cell is provided by two shared bit-or-source lines coupled to the respective combined memory cell. In embodiments, adjacent ones of the plurality of combined memory cells are configured to share a same one of the shared bit-or-source lines.

The above embodiment, for reading a nonvolatile memory content of a first memory transistor, is adapted to apply a first source voltage to a first shared bit-or-source line of a combined memory cell, wherein the first shared bit-or-source line is connected to a source/drain of the first memory transistor. This embodiment is further adapted to apply a first bitline voltage to a second shared bit-or-source line of the combined memory cell, wherein the second shared bit-or-source line is connected to a drain/source of a second memory transistor. Moreover, the embodiment is adapted to apply a first read voltage to a first control gate line of the combined memory cell, wherein the first control gate line is connected to a control gate of the first memory transistor. Furthermore, the embodiment is adapted to apply a first select voltage to a select gate line of the combined memory cell, wherein the select gate line is connected to a gate of the select transistor. Finally, this embodiment is adapted to apply a second read voltage to a second control gate line of the combined memory cell, wherein the second control gate line is connected to a control gate of the second memory transistor, and wherein the second read voltage is greater than the first read voltage.

The above embodiment, for reading a nonvolatile memory content of the second memory transistor, is further adapted to apply a second bitline voltage to the first shared bit-or-source line of the combined memory cell, apply a second source voltage to the second shared bit-or-source line of the combined memory cell, apply a third read voltage to the first control gate line of the combined memory cell, apply the first select voltage to the select gate line of the combined memory cell, and apply a fourth read voltage to the second control gate line of the combined memory cell, wherein the third read voltage is greater than the fourth read voltage.

The latter embodiment, for programming a nonvolatile memory content of the first memory transistor, is further adapted to apply a third bitline voltage to the first shared bit-or-source line of the combined memory cell, apply a third source voltage to the second shared bit-or-source line of the combined memory cell, apply a first program voltage to the first control gate line of the combined memory cell, apply a second select voltage to the select gate line of the combined memory cell, and apply a second program voltage to the second control gate line of the combined memory cell, wherein the first program voltage is greater than the second program voltage.

The above embodiment, for programming a nonvolatile memory content of the second memory transistor, is further adapted to apply a fourth source voltage to the first shared bit-or-source line of the combined memory cell, apply a fourth bitline voltage to the second shared bit-or-source line of the combined memory cell, apply a third program voltage to the first control gate line of the combined memory cell, apply the second select voltage to the select gate line of the combined memory cell, and apply a fourth program voltage to the second control gate line of the combined memory cell, wherein the fourth program voltage is greater than the third program voltage.

The above embodiment, for erasing a nonvolatile memory content of the first memory transistor and the second memory transistor, is further adapted to apply a fifth bitline voltage to the first shared bit-or-source line of the combined memory cell, apply the fifth bitline voltage to the second shared bit-or-source line of the combined memory cell, apply a first erase voltage to the first control gate line of the combined memory cell, apply a third select voltage to the select gate line of the combined memory cell, apply the first erase voltage to the second control gate line of the combined memory cell and apply a second erase voltage to a bulk contact of the combined memory cell.

A further embodiment relates to a nonvolatile memory device comprising a plurality of two-bit memory cells each comprising a first nonvolatile memory element, a second nonvolatile memory element, and a common selection element for selecting one of the plurality of two-bit memory cells for a read operation or a program operation.

In an embodiment, the first nonvolatile memory element and the second nonvolatile memory element comprises a first memory transistor and a second memory transistor respectively. Moreover, the common selection element comprises a select transistor coupled with its drain and source between the source or drain of the first memory transistor and the drain or source of the second memory transistor respectively. In this embodiment, the drain or source of the first memory transistor is coupled to a first shared bit-or-source line and the source or drain of the second memory transistor is coupled to a second shared bit-or-source line.

The above embodiment, for copying a nonvolatile memory content to the first memory transistor from the second memory transistor, is adapted to apply a first bitline voltage to the first shared bit-or-source line of a particular one of the two-bit memory cells, apply a first source voltage to the second shared bit-or-source line of the particular one of the two-bit memory cells, apply a first copy voltage to the first control gate line of the particular one of the two-bit memory cells, wherein the first control gate line is connected to a control gate of the first memory transistor, apply a first select voltage to the select gate line of the particular one of the two-bit memory cells, wherein the select gate line is connected to a gate of the select transistor, apply a second copy voltage to the second control gate line of the particular one of the two-bit memory cells, wherein the first copy voltage is greater than the second copy voltage.

Another embodiment relates to a method for managing two bits of information in each of a plurality of nonvolatile memory cells comprising sharing, in each of the memory cells each comprising at least two nonvolatile memory elements, one select element for selecting one of the at least two nonvolatile memory elements of a particular one of the memory cells for a read operation or a program operation.

In an embodiment, the nonvolatile memory elements comprise at least a first memory transistor and a second memory transistor in each of the memory cells, wherein the select element comprises a select transistor in each of the memory cells.

In a further embodiment according to the above method, the managing two bits of information comprises applying a higher voltage to a control gate of the first memory transistor of a particular one of the memory cells than to a control gate of the second memory transistor of the particular one of the memory cells to read a nonvolatile memory content of the second memory transistor.

In a further embodiment according to the above method, the managing two bits of information comprises programming data to the first memory transistor of a particular one of the memory cells in case the second memory transistor of the particular one of the memory cells is in erased state, and leaving the first memory transistor of the particular one of the memory cells in erased state in case the second memory transistor of the particular one of the memory cells is in a programmed state.

In a still further embodiment according to the above method, the managing two bits of information comprises copying data to the first memory transistor from the second memory transistor by applying a program voltage to a control gate of the first memory transistor, applying a select voltage to a gate of the select transistor, and applying a read voltage to a control gate of the second memory transistor, wherein the program voltage is greater than the read voltage.

A further embodiment relates to a method for managing two bits of information in each of a plurality of nonvolatile memory cells wherein each nonvolatile memory cell comprises a first memory transistor, a second memory transistor and a select transistor.

An embodiment of the latter method for reading a nonvolatile memory content of a first memory transistor further comprises applying a first source voltage to a first shared bit-or-source line of a particular one of the plurality of memory cells, wherein the first shared bit-or-source line is connected to a source/drain of the first memory transistor. The device in one embodiment comprising biasing circuitry associated with the memory, for example, in the peripheral portion thereof that is configured to generate one or more biasing signals for appropriate biasing of various terminals of the memory device. This embodiment further comprises applying a first bitline voltage to a second shared bit-or-source line of the particular one of the plurality of memory cells, wherein the second shared bit-or-source line is connected to a drain/source of a second memory transistor. Moreover, this embodiment comprises applying a first read voltage to a first control gate line of the particular one of the plurality of memory cells, wherein the first control gate line is connected to a control gate of the first memory transistor. Furthermore, this embodiment comprises applying a first select voltage to a select gate line of the particular one of the plurality of memory cells, wherein the select gate line is connected to a gate of the select transistor. Finally, this embodiment comprises applying a second read voltage to a second control gate line of the particular one of the plurality of memory cells, wherein the second control gate line is connected to a control gate of the second memory transistor, wherein the second read voltage is greater than the first read voltage.

An embodiment according to the latter method for reading a nonvolatile memory content of the second memory transistor further comprises applying a second bitline voltage to the first shared bit-or-source line of the particular one of the plurality of memory cells, applying a second source voltage to the second shared bit-or-source line of the particular one of the plurality of memory cells, applying a third read voltage to the first control gate line of the particular one of the plurality of memory cells, applying the first select voltage to the select gate line of the particular one of the plurality of memory cells, applying a fourth read voltage to the second control gate line of the particular one of the plurality of memory cells, wherein the third read voltage is greater than the fourth read voltage.

A further embodiment according to the latter method for programming a nonvolatile memory content of the first memory transistor further comprises applying a third bitline voltage to the first shared bit-or-source line of the particular one of the plurality of memory cells, applying a third source voltage to the second shared bit-or-source line of the particular one of the plurality of memory cells, applying a first program voltage to the first control gate line of the particular one of the plurality of memory cells, applying a second select voltage to the select gate line of the particular one of the plurality of memory cells; applying a second program voltage to the second control gate line of the particular one of the plurality of memory cells, wherein the first program voltage is greater than the second program voltage.

An embodiment according to the latter method for programming a nonvolatile memory content of the second memory transistor further comprises applying a fourth source voltage to the first shared bit-or-source line of the particular one of the plurality of memory cells, applying a fourth bitline voltage to the second shared bit-or-source line of the particular one of the plurality of memory cells, applying a third program voltage to the first control gate line of the particular one of the plurality of memory cells, applying the second select voltage to the select gate line of the particular one of the plurality of memory cells, applying a fourth program voltage to the second control gate line of the particular one of the plurality of memory cells, wherein the fourth program voltage is greater than the third program voltage.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this disclosure be limited only by the claims and the equivalents thereof.

1-27. (canceled)

28. A method for managing information in each of a plurality of nonvolatile memory cells, comprising:
sharing, in each of the memory cells each comprising at least two nonvolatile memory elements, one select element for selecting one of the at least two nonvolatile memory elements of a particular one of the memory cells for a read operation or a program operation.

29. The method of claim 28, wherein the nonvolatile memory elements comprise at least a first memory transistor and a second memory transistor in each of the memory cells.

30. The method of claim 29, wherein the select element comprises a select transistor in each of the memory cells.

31. The method of claim 30, wherein managing information comprises:
copying data to the first memory transistor from the second memory transistor.

32. The method of claim 31, wherein copying data to the first memory transistor from the second memory transistor comprises:
applying a program voltage to a control gate of the first memory transistor;
applying a select voltage to a gate of the select transistor; and
applying a read voltage to a control gate of the second memory transistor.

33. The method of claim 32, wherein the program voltage is greater than the read voltage.

34. The method of claim 29, wherein managing information comprises applying a higher voltage to a control gate of the first memory transistor of a particular one of the memory cells than to a control gate of the second memory transistor of the particular one of the memory cells to read a nonvolatile memory content of the second memory transistor.

35. The method of claim 29, wherein managing information comprises:
programming data to the first memory transistor of a particular one of the memory cells in case the second memory transistor of the particular one of the memory cells is in an erased state; and
leaving the first memory transistor of the particular one of the memory cells in an erased state in case the second memory transistor of the particular one of the memory cells is in a programmed state.

36. A nonvolatile memory device, comprising:
a plurality of nonvolatile memory elements, wherein sets of at least two nonvolatile memory elements each share one select element for selecting one of the nonvolatile memory elements of a particular one of the sets of nonvolatile memory elements for a read operation or a program operation.

37. The memory device of claim 36,
wherein the sets of nonvolatile memory elements each comprise at least a first memory transistor and a second memory transistor, and
wherein the select element in each of the sets of nonvolatile memory elements comprises a select transistor.

38. The memory device of claim 37, wherein a memory functionality of the first and the second memory transistor is based on a floating gate, a nitride layer or a nanocrystal layer.

39. The memory device of claim 37, further comprising biasing circuitry configured to apply a higher voltage to a control gate of the first memory transistor of a particular one of the sets of nonvolatile memory elements forming a combined memory cell than to a control gate of the second memory transistor of the combined memory cell to program the first memory transistor.

40. The memory device of claim 39, the biasing circuitry configured to apply a lower voltage to a control gate of the select transistor than to the control gate of the first memory transistor and the control gate of the second memory transistor of the particular one of the sets of nonvolatile memory elements forming the combined memory cell to program the first memory transistor.

41. The memory device of claim 40, the biasing circuitry configured to apply a lower voltage to respective bulk terminals of the select transistor, the first memory transistor, and the second memory transistor than to the control gate of the select transistor, the first memory transistor, and the second memory transistor to program the first memory transistor.

42. The memory device of claim 37, further comprising biasing circuitry configured to apply a higher voltage to a control gate of the first memory transistor of a particular one of the sets of nonvolatile memory elements forming a combined memory cell than to a control gate of the second memory transistor of the combined memory cell to read a nonvolatile memory content of the second memory transistor.

43. The memory device of claim 36, further comprising biasing circuitry for complement sensing of nonvolatile memory contents, configured to provide biasing signals to:
program data to one of a set of two nonvolatile memory elements in case the other of the set of two nonvolatile memory elements is in an erased state; and
leave the one of the set of two nonvolatile memory elements in an erased state in case the other of the set of two nonvolatile memory elements is in a programmed state.

44. The memory device of claim 36, further comprising biasing circuitry configured to provide biasing signals to copy data to one of a set of two nonvolatile memory elements from the other of the set of two nonvolatile memory elements.

45. A nonvolatile memory device, comprising:
a plurality of two-bit memory cells each comprising:
a first nonvolatile memory element;
a second nonvolatile memory element; and
a common selection element for selecting one of the plurality of two-bit memory cells for a read operation or a program operation.

46. The memory device of claim 45,
wherein the first nonvolatile memory element and the second nonvolatile memory element comprises a first memory transistor and a second memory transistor respectively;
wherein the common selection element comprises a select transistor coupled with its drain and source between the source or drain of the first memory transistor and the drain or source of the second memory transistor, respectively;
wherein the drain or source of the first memory transistor is coupled to a first shared bit-or-source line and the source or drain of the second memory transistor is coupled to a second shared bit-or-source line.

47. The memory device of claim 46, further comprising biasing circuitry configured to provide biasing signals for copying a nonvolatile memory content to the first memory transistor from the second memory transistor.

48. The memory device of claim 47, the biasing circuitry configured to:
apply a first bitline voltage to the first shared bit-or-source line of a particular one of the two-bit memory cells;
apply a first source voltage to the second shared bit-or-source line of the particular one of the two-bit memory cells;
apply a first copy voltage to a first control gate line of the particular one of the two-bit memory cells, the first control gate line connected to a control gate of the first memory transistor;
apply a first select voltage to a select gate line of the particular one of the two-bit memory cells.

49. The memory device of claim 48, wherein the select gate line is connected to a gate of the select transistor.

50. The memory device of claim 48, the biasing circuitry configured to:
apply a second copy voltage to a second control gate line of the particular one of the two-bit memory cells.

51. The memory device of claim 50, wherein the first copy voltage is greater than the second copy voltage.
